(19) United States
(12) Patent Application Publication
(10) Pub. No.: US 2026/0279663 A1
(43) Pub. Date: Sep. 17, 2026

(54) MOUNTING STRUCTURE FOR ELECTRONIC COMPONENT

(71) Applicant: Murata Manufacturing Co., Ltd., Nagaokakyo-shi (JP)

(72) Inventors: Takahito SHIMIZU, Nagaokakyo-shi (JP); Yuta KUROSU, Nagaokakyo-shi (JP); Masato KIMURA, Nagaokakyo-shi (JP)

(73) Assignee: Murata Manufacturing Co., Ltd., Nagaokakyo-shi (JP)

(21) Appl. No.: 19/666,392

(22) Filed: May 4, 2026

Related U.S. Application Data
(63) Continuation of application No. PCT/JP2024/036752, filed on Oct. 16, 2024.

(30) Foreign Application Priority Data
Dec. 27, 2023 (JP) 2023-221499

(51) Int. Cl. H01G 2/06; H01G 4/30; H05K 1/181

(52) U.S. Cl. CPC H01G 2/065; H05K 1/181; H01G 4/30; H05K 2201/10015; H05K 2201/10636

(57) ABSTRACT

A mounting configuration includes a pair of lands on a substrate, an electronic component including a component main body and a pair of external electrodes, each external electrode having an extension portion, and solder connecting the external electrodes to the lands. When a direction in which a pair of lands are aligned is defined as an X direction, a direction in which the pair of lands are spaced apart is defined as a spacing direction, and a direction in which the pair of lands are opposed to each other is defined as an opposing direction, an opposing direction end portion of solder is located in the X direction at a position between an opposing direction end portion of the extension portion and a spacing direction end portion of a corresponding external electrode or at the spacing direction end portion of the corresponding external electrode.

### CROSS-REFERENCE TO RELATED APPLICATIONS

This application is a continuation of International Application No. PCT/JP2024/036752, filed on Oct. 16, 2024, which claims the benefit of priority to Japanese Patent Application No. 2023-221499, filed on Dec. 27, 2023. The entire contents of each of the above-identified applications are incorporated herein by reference.

### TECHNICAL FIELD

The present disclosure relates to a mounting configuration of an electronic component.

### BACKGROUND ART

Conventionally, two-terminal electronic components such as multilayer ceramic capacitors and inductors are mounted on a substrate having a circuit by soldering. Patent Document 1 discloses a mounting configuration in which a pair of external electrodes provided at both end portions in the length direction of a multilayer ceramic capacitor are connected to a pair of electrode pads provided on a substrate by soldering, respectively.

### CITATION LIST

### Patent Document

Patent Document 1: Japanese Unexamined Patent Application, Publication No. 2014-086606

### SUMMARY

When the environmental temperature changes during use of electronic equipment, stress is generated in the electronic component due to differences in the linear expansion coefficients of the electronic component, solder, and substrate. When stress is generated in the electronic component, cracks may occur at the boundary between the base body and the external electrode. In addition, when electronic components with such cracks are exposed to a humid environment, the internal insulation resistance may decrease and generate heat, which may damage the electronic equipment.

An embodiment of the present disclosure provides a mounting configuration of an electronic component that suppresses the occurrence of cracks. The mounting configuration includes a pair of lands on a substrate and spaced apart from each other, an electronic component having a component main body with laminated dielectric layers and internal electrode layers and a pair of external electrodes on opposite end surfaces, and solder connecting each external electrode to a corresponding land. Each external electrode includes an extension portion extending onto at least a portion of a main surface of the component main body. When a direction in which the pair of lands are aligned is defined as an X direction, a direction in which the pair of lands are spaced apart is defined as a spacing direction, and a direction in which the pair of lands are opposed to each other is defined as an opposing direction, an opposing direction end portion of the solder is located in the X direction at a position between an opposing direction end portion of the extension portion and a spacing direction end portion of a corresponding external electrode or at the spacing direction end portion of the corresponding external electrode.

According to an embodiment, a mounting configuration of an electronic component that is able to suppress the occurrence of cracks in the electronic component may be provided.

### BRIEF DESCRIPTION OF THE DRAWINGS

FIG. 1 is a perspective view showing a multilayer ceramic capacitor as an electronic component applied to the mounting configuration of an electronic component according to a first embodiment.

FIG. 2 is a plan view showing the mounting configuration of an electronic component according to the first embodiment.

FIG. 3 is a cross-sectional view taken along the line III-III of FIG. 2.

FIG. 4 is a partially enlarged cross-sectional view showing a main portion of the mounting configuration of an electronic component according to the first embodiment.

FIG. 5 is a partially enlarged cross-sectional view showing a main portion of the mounting configuration of an electronic component according to a second embodiment.

FIG. 6 is a partially enlarged cross-sectional view showing a main portion of the mounting configuration of an electronic component according to a third embodiment.

FIG. 7 is a partially enlarged cross-sectional view showing a main portion of the mounting configuration of an electronic component according to a fourth embodiment.

FIG. 8 is a partially enlarged cross-sectional view showing a main portion of the mounting configuration of an electronic component according to a fifth embodiment.

FIG. 9 is a partially enlarged cross-sectional view showing a main portion of the mounting configuration of an electronic component according to a sixth embodiment.

FIG. 10 is a partially enlarged cross-sectional view showing a main portion of the mounting configuration of an electronic component according to a seventh embodiment.

### DETAILED DESCRIPTION

Hereinafter, embodiments will be described with reference to the drawings.

### First Embodiment

### (Multilayer Ceramic Capacitor)

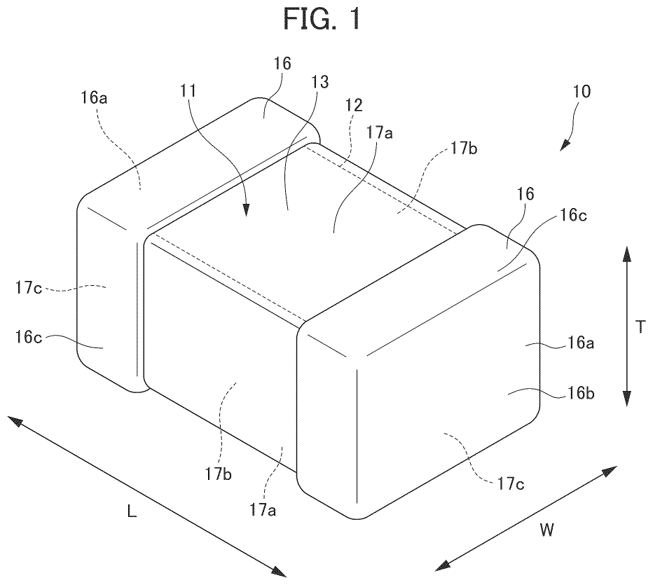

Based on FIG. 1, an outline of the configuration of a multilayer ceramic capacitor 10 will be described. FIG. 1 shows the multilayer ceramic capacitor 10 as an electronic component applied to the mounting configuration of electronic components according to the first embodiment. The first embodiment is one form of a configuration for mounting the multilayer ceramic capacitor 10 on a substrate.

The multilayer ceramic capacitor 10 has a substantially rectangular parallelepiped shape as a whole. The multilayer ceramic capacitor 10 includes a component main body 11 and a pair of external electrodes 16. The component main body 11 includes an inner layer portion 12 including a plurality of dielectric layers 121 and internal electrode layers 122 that are alternately laminated.

In the present specification, the direction in which the dielectric layers 121 and the internal electrode layers 122 are laminated or stacked is referred to as “lamination direction T”. The direction perpendicular to the lamination direction T is referred to as “length direction L”. The direction perpendicular to the lamination direction T and the length direction L is referred to as “width direction W”. The pair of external electrodes 16 are aligned in the length direction L.

The dimensions of the multilayer ceramic capacitor 10 can be exemplified as, for example, the length direction L of 0.2 mm or more and 1.7 mm or less, the width direction W of 0.12 mm or more and 0.9 mm or less, and the lamination direction T of 0.12 mm or more and 0.9 mm or less, but are not limited thereto.

### (Component Main Body)

The component main body 11 has a substantially rectangular parallelepiped shape. The component main body 11 includes a pair of main surfaces 17a opposed to each other in the lamination direction T, a pair of lateral surfaces 17b opposed to each other in the width direction W, and a pair of end surfaces 17c opposed to each other in the length direction L.

The component main body 11 includes the inner layer portion 12 inside thereof. The inner layer portion 12 has a multilayer configuration in which a plurality of internal electrode layers 122 and a plurality of dielectric layers 121 are alternately laminated in the lamination direction T. Four surfaces on both sides in the width direction W and both sides in the lamination direction T of the inner layer portion 12 are covered with outer layer dielectric ceramic layers 13 made of the same material as the dielectric ceramic layers.

### (Internal Electrode Layer)

Each of the internal electrode layers 122 is made of a metal material represented by Ni, Cu, Ag, Pd, an Ag—Pd alloy, Au, or the like, but is not limited to these metal materials, and may be made of other electrically conductive materials.

### (Dielectric Layer)

The dielectric layers 121 and the outer dielectric ceramic layers 13 are formed by firing, for example, a ceramic material including barium titanate as a main component, or other high permittivity ceramic materials (for example, materials including CaTiO₃, SrTiO₃, CaZrO₃, or the like as a main component).

### (External Electrode)

The pair of external electrodes 16 are provided at both end portions in the length direction L of the component main body 11, respectively. Each of the external electrodes 16 covers a corresponding one of the pair of end surfaces 17c of the component main body 11. The pair of external electrodes 16 may also be provided on a portion of the pair of main surfaces 17a and a portion of the pair of lateral surfaces 17b, respectively. In the plurality of internal electrode layers 122 in the inner layer portion 12, one of internal electrode layers adjacent to each other in the lamination direction T is connected to one of the external electrodes 16, and the other is connected to the other external electrode. Each of the pair of external electrodes 16 has an end surface 16a in the length direction L.

Each of the external electrodes 16 includes, for example, a laminated film of a sintered metal layer and a plated layer. The sintered metal layer is formed by firing a paste of, for example, Cu, Ni, Ag, Pd, Ag—Pd alloy, Au, or the like. The plated layer includes, for example, a Ni plated layer and a Sn plated layer covering the Ni plated layer.

The multilayer ceramic capacitor 10 is manufactured, for example, by forming the pair of external electrodes 16 by firing or plating after the component main body 11 is fired. A portion of the external electrode 16 may be fired simultaneously with the component main body 11, and then the plated layer of the external electrode 16 may be formed.

### (Mounting Configuration)

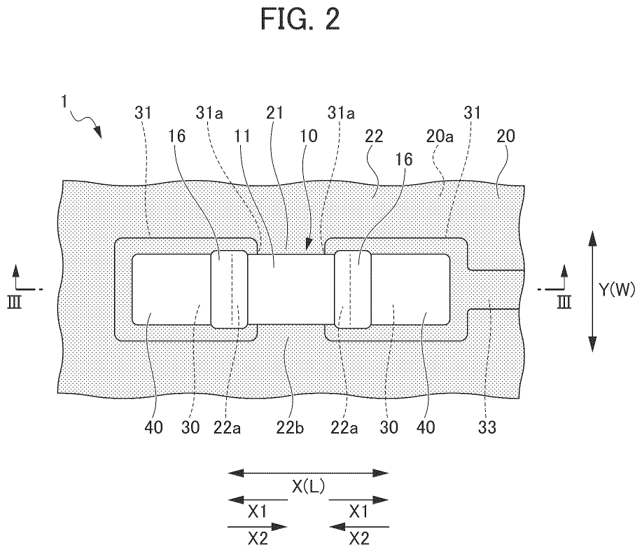

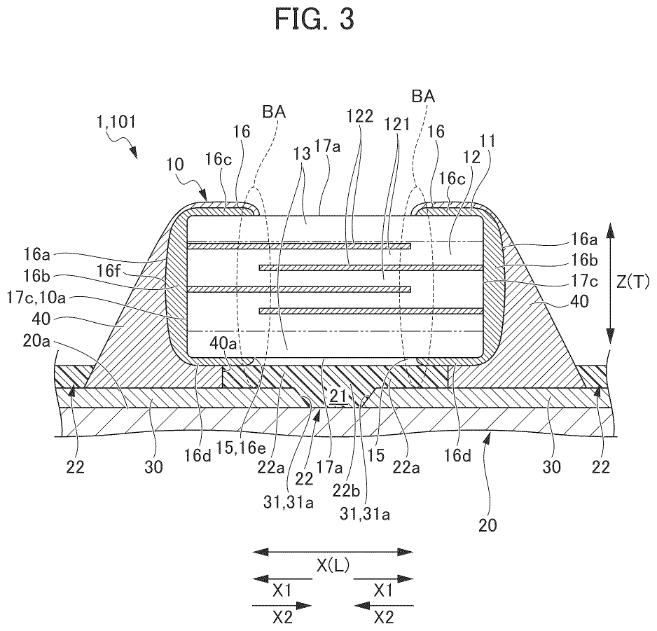

With reference to FIG. 2 and FIG. 3, the mounting configuration 1 of the first embodiment will be described. In order to distinguish from the mounting configuration 1 of other embodiments, the mounting configuration 1 of the first embodiment is referred to as mounting configuration 101. The same applies to other embodiments.

As shown in FIG. 2 and FIG. 3, the mounting configuration 101 of the first embodiment includes a substrate 20, a pair of lands 30 provided on the substrate 20 and spaced apart from each other in an opposed manner, solder 40 provided on each of the lands 30 with at least a portion thereof provided thereon, and the multilayer ceramic capacitor 10. The multilayer ceramic capacitor 10 is mounted on the substrate 20 by soldering.

### (Substrate)

The substrate 20 is formed in a sheet shape from a material made of an insulating material such as resin, glass, glass epoxy, paper phenol, or ceramics.

Wiring 33 is formed on the surface 20a of the substrate 20. The wiring 33 is provided in a discontinuous state with the spacing portion 21 interposed therebetween, and a pair of lands 30, which are portions of the wiring 33 connected to the external electrodes 16, are exposed on both sides of the spacing portion 21. The pair of lands 30 are provided on the surface 20a of the substrate 20 spaced apart from each other. Therefore, the spacing portion 21 can also be referred to as a region between the pair of lands 30. Each of the pair of lands 30 are provided in parallel with each other such that positions in a direction orthogonal to a direction in which the lands 30 are aligned are the same as each other.

### (Wiring and Land)

The wiring 33 including the land 30 is formed by depositing a highly conductive metal such as Cu or Ag on the surface 20a of the substrate 20. Each of the pair of lands 30 has a rectangular shape in a plan view and has substantially the same shape and dimensions as each other.

### (Spacing Direction and Opposing Direction)

In this specification, a direction orthogonal to the surface 20a of the substrate 20 is defined as “Z direction”. A direction orthogonal to the Z direction and in which the pair of lands 30 are aligned is defined as “X direction”. A direction orthogonal to the X direction and the Z direction is defined as “Y direction”. In the X direction, a direction in which the pair of lands 30 are spaced apart from each other is defined as “spacing direction X1”, and a direction in which the pair of lands 30 oppose each other is defined as “opposing direction X2”. Also, “thickness of the land” indicates a dimension of the land 30 in the Z direction.

The peripheral edge portions of the pair of lands 30 in the X direction and Y direction are defined as “peripheral edge portions 31”. In each of the peripheral edge portions 31, an edge adjacent to the spacing portion 21 is defined as “inner edge 31a”. The inner edge 31a has a linear shape extending in the Y direction.

### (Insulating Film)

The surface 20a of the substrate 20 is covered with an insulating film 22. The insulating film 22 includes an insulating material such as a solder resist. However, the present disclosure is not limited to this, and as the insulating material that constitutes the insulating film 22, it is possible to suitably use an insulating coating material for substrates having a resin as a main component such as polyolefin resin, acrylic resin, polyurethane resin, or the like. The insulating film 22 extends to above each land 30, and a portion of each land 30 adjacent to the peripheral edge portion 31 is covered with the insulating film 22. The peripheral edge portion 31 of each land 30 is covered with the insulating film 22. In the spacing portion 21, the surface 20a of the substrate 20 is covered with the insulating film 22. In FIG. 2, the portion where the insulating film 22 is provided is indicated by dot hatching.

### (On-Land Insulating Film and Inter-Spacing Portion Insulating Film)

A portion of the insulating film 22 provided on the surface of each land 30 is referred to as “on-land insulating film 22a”, and a portion provided in a region that overlaps with the spacing portion 21 when viewed in the Z direction is referred to as “inter-spacing portion insulating film 22b”. The insulating film 22 provided in the spacing portion 21 is included in the inter-spacing portion insulating film 22b. When the inner edge 31a of each of the lands 30 is a sloped surface that slopes in a direction approaching the substrate 20 as it extends in the opposing direction X2, the insulating film 22 provided in a region that overlaps with the sloped surface when viewed in the Z direction is included in the inter-spacing portion insulating film 22b and is not included in the on-land insulating film 22a. In the present specification, “thickness of the insulating film 22” indicates the dimension of the insulating film 22 in the Z direction.

The multilayer ceramic capacitor 10 mounted on the substrate 20 has the length direction L substantially along the X direction, the width direction W substantially along the Y direction, and the lamination direction T substantially along the Z direction. As a result, one main surface 17a of the component main body 11 is opposed to the surface 20a of the substrate 20 substantially in a parallel manner. The multilayer ceramic capacitor 10 does not necessarily have to be mounted on the substrate 20 with the main surface 17a facing the substrate 20, and may be mounted on the substrate 20 with one lateral surface 17b facing the substrate 20.

The multilayer ceramic capacitor 10 has one external electrode 16 connected to one land 30 via solder 40, and the other external electrode 16 connected to the other land 30 via solder 40. As shown in FIG. 3, each end surface 16a of each external electrode 16 is substantially covered with solder 40. The end surface 16a of each of the external electrodes 16 may be partially covered with solder 40. The multilayer ceramic capacitor 10 is provided such that the middle in the width direction W substantially coincides with the middle in the width direction W of each land 30.

### (Extension Portions of External Electrodes)

Each of the pair of external electrodes 16 includes a flat end surface covering portion 16b that covers the end surface 17c of the component main body 11, and an extension portion 16c that extends from the end surface covering portion 16b in the opposing direction X2 and is provided on portions of the pair of main surfaces 17a and the pair of lateral surfaces 17b. Each of the extension portions 16c covers only a portion adjacent to the end surface 17c side of each surface of the main surfaces 17a and the lateral surfaces 17b. Each of the extension portions 16c has a rectangular tubular shape as a whole. The end portion of each of the extension portions 16c in the opposing direction X2 corresponds to a boundary portion between the external electrode 16 and the component main body 11 (hereinafter referred to as “boundary portion 15”). Each of the extension portions 16c does not necessarily have a rectangular tubular shape as a whole. Each of the extension portions 16c does not need to extend to all surfaces among each of the main surfaces 17a and each of the lateral surfaces 17b, and it is only required that the extension portion 16c extends to at least one surface among the main surfaces 17a and the lateral surfaces 17b that is opposed to the substrate 20.

### (Land-Opposing Extension Portion and Extension Portion End)

The extension portion 16c covering one main surface 17a of the component main body 11 that opposes the substrate 20 is connected to the land 30 via solder 40. In the extension portion 16c, the extension portion 16c that covers one main surface 17a opposing the substrate 20 among the two main surfaces 17a of the component main body 11 and is connected to the land 30 via solder 40 or directly is referred to as a land opposing extension portion 16d.

### (Extension Portion End)

The end portion of each of the land opposing extension portions 16d in the opposing direction X2 is referred to as an extension portion end portion 16e. The extension portion end portion 16e (the boundary portion 15) is located more in the spacing direction X1 than the inner edge 31a of the land 30 connected to the land opposing extension portion 16d.

In addition, the end portion of the land opposing extension portion 16d in the opposing direction X2 (the boundary portion 15) may be located more in the opposing direction X2 than the inner edge 31a of the land 30 connected to the land opposing extension portion 16d, or may be located at substantially the same position as the inner edge 31a. In this case, the on-land insulating film 22a may be provided between the land opposing extension portion 16d and the land 30, or the on-land insulating film 22a may not be provided. Such a configuration will be described later.

### (Solder End Portion)

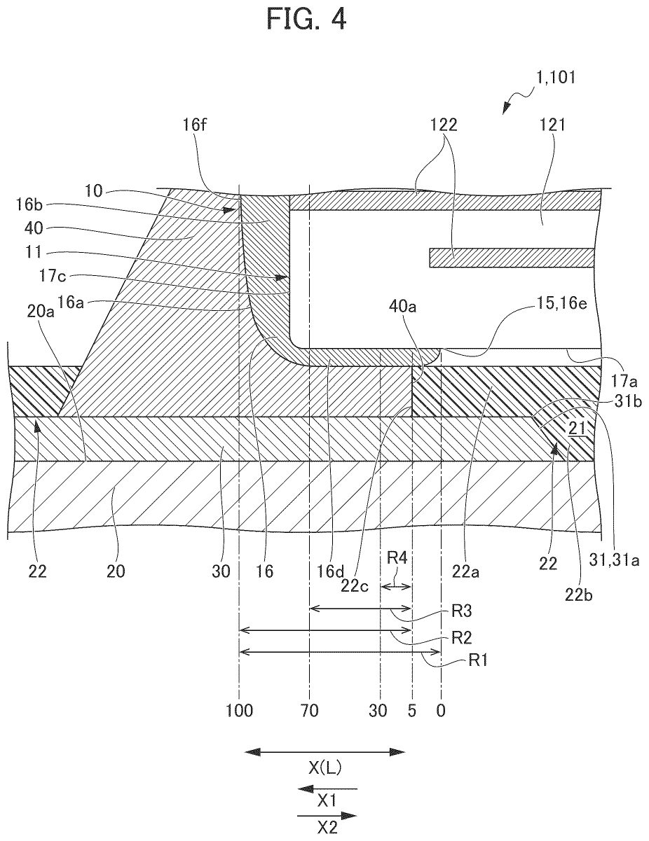

With reference to FIG. 4, the position of the opposing direction end portion 40a will be described. FIG. 4 is a partially enlarged cross-sectional view showing a main portion of the mounting configuration 101 of the multilayer ceramic capacitor 10 according to the first embodiment. In the mounting configuration 101 of the first embodiment, the solder 40 does not reach the component main body 11 beyond the land opposing extension portion 16d. That is, the solder 40 is not in contact with the component main body 11.

### (Extension Portion End Portion and Spacing Direction End Portion)

The end of the land opposing extension portion 16d in the opposing direction X2 is referred to as the extension portion end portion 16e. The end of each of the external electrodes 16 in the spacing direction X1 is referred to as a spacing direction end portion 16f. The spacing direction end portion 16f refers to a portion that is located most in the spacing direction X1 at the end surface 16a of each of the external electrodes 16 in the length direction L.

### (Solder End Portion)

The end portion of the solder 40 on each of the lands 30 in the opposing direction X2 is defined as the opposing direction end portion 40a.

### (Position of Solder End Portion)

In the mounting configuration 101 of the first embodiment, the opposing direction end portion 40a is located in any one of between the extension portion end portion 16e and the spacing direction end portion 16f or at the spacing direction end portion 16f in the X direction.

By locating the opposing direction end portion 40a at such a position, the solder 40 does not exist on the extension portion end portion 16e and beyond the extension portion end portion 16e in the opposing direction X2. This makes it possible to suppress the solder 40 from contacting the component main body 11.

### (Insulating Film End Portion)

Next, the placement of the insulating film 22 will be described. An end portion of the insulating film 22 in the spacing direction X1 is defined as an insulating film end portion 22c. In the example shown in FIG. 4, the insulating film end portion 22c is in contact with the opposing direction end portion 40a. By locating the insulating film end portion 22c at any one among at the extension portion end portion 16e, between the extension portion end portion 16e and the spacing direction end portion 16f, or at the spacing direction end portion 16f, it is possible to suppress the opposing direction end portion 40a from being located on the extension portion end portion 16e and beyond the extension portion end portion 16e. As a result, it is possible to reliably suppress the solder 40 from contacting the component main body 11.

Next, a position in the X direction of the opposing direction end portion 40a on the land 30 will be described. As shown in FIG. 4, a range from the extension portion end portion 16e to the spacing direction end portion 16f is defined as a range R1. The length of the range R1 is set to 100. In the range R1, the position of the extension portion end portion 16e is set to 0, and the position of the spacing direction end portion 16f is set to 100. The position of the opposing direction end portion 40a in the range R1 is 0≤ position of the opposing direction end portion 40a≤100. That is, the opposing direction end portion 40a is located at any one of between the extension portion end portion 16e and the spacing direction end portion 16f or at the spacing direction end portion 16f. This makes it possible to ensure electrical connection between the land opposing extension portion 16d and the land 30, while reliably suppressing the solder 40 from contacting the component main body 11.

The position of the opposing direction end portion 40a in the range R1 may be 5≤position of the opposing direction end portion 40a≤100 (range R2). In addition, the position of the end surface 17c may be 5≤position of the end surface 17c≤55 in the range R1. The numbers such as 5 and 30 related to the range R1 shown in FIG. 4 indicate approximate positions.

The position of the opposing direction end portion 40a in the range R1 is 5≤position of the opposing direction end portion 40a≤70 (range R3). This makes it easier for the solder 40 to cover a thick portion in the lamination direction T in the land opposing extension portion 16d. The position of the opposing direction end portion 40a may be in the range R1 is 5≤position of the opposing direction end portion 40a≤30 (range R4). This makes it possible to suppress a decrease in bonding strength of the solder 40.

### (Solder Material)

The solder 40 is not particularly limited in type as long as it has characteristics compatible with each external electrode 16 and each land 30, and may be, for example, Sn—Pb solder, Sn—Ag—Cu solder, Sn—Cu solder, Sn—Bi solder, or the like.

### (Cracks)

Stress may act on the ceramic sintered body near the tip portion of the external electrode 16 due to thermal shock or the like. In this case, cracks may occur in the component main body 11 starting from the boundary portion 15 between the edge of the land opposing extension portion 16d of the external electrode 16 and the component main body 11. The region where such cracks are likely to occur is shown in FIG. 3 by the dotted line enclosure BA.

Therefore, the solder 40 may not reach the component main body 11 beyond the land opposing extension portion 16d. The solder 40 may not contact the component main body 11. In this case, it is possible to suppress stress from being applied to the boundary portion 15, and thus it is possible to suppress the occurrence of cracks. In addition, it is possible to suppress not only stress caused by thermal shock, but also stress caused by deflection of the substrate 20 from acting on the boundary portion 15.

As shown in FIG. 3, the opposing direction end portion 40a of the solder 40 is set back in the spacing direction relative to the boundary portion BA where the extension portion 16d meets the component main body 11. This set back configuration ensures that a gap exists between the solder 40 and the ceramic material of the component main body 11, thereby preventing the transmission of mechanical stress from the substrate 20 directly to the component main body 11 via the solder 40.

Furthermore, as shown in FIG. 3 and FIG. 4, the solder 40 formed between the land 30 and the external electrode 16 (specifically the extension portion 16d and the end surface portion 16a) may form a solder fillet having a concave profile. This concave profile is characterized by a surface that curves inward toward the electronic component 10. By maintaining this concave profile and ensuring that the solder does not bulge significantly outward, the mechanical stress concentrated at the boundary portion BA is further reduced, and the risk of the solder 40 accidentally overflowing to contact the component main body 11 is minimized. Furthermore, in a Z direction (thickness direction) perpendicular to the main surface of the substrate 20, the maximum height of the solder 40 from the surface of the land 30 is configured to be less than the height of the electronic component 10. By limiting the height of the solder 40 such that it does not reach the upper main surface of the electronic component 10, the volume of the solder 40 is controlled to prevent excessive stress at the boundary portion BA and to ensure that the solder 40 does not overflow onto the top of the component main body 11, which could lead to mechanical cracking.

In the first embodiment, the thickness of the on-land insulating film 22a may be adjusted appropriately according to the thickness of the solder 40 on the land 30.

The thicknesses of the insulating film 22, the land 30, and the solder 40 provided on the land 30 are measured, for example, in a cross section obtained by cutting the mounting configuration 101 of the first embodiment parallel to the X direction and the Z direction so as to pass through the middle portion of the multilayer ceramic capacitor 10 in the Y direction. The thickness value of the solder 40 is, for example, an average value of values obtained by measuring the thickness of the solder 40 at a plurality of positions (for example, three positions) provided at equal intervals in the X direction in the cross section. The same applies to the insulating film 22 and the land 30.

In the first embodiment, soldering with the solder 40 is performed, for example, by reflow. That is, the multilayer ceramic capacitor 10 can be reflow-mounted on the substrate 20. Hereinafter, a mounting method for the multilayer ceramic capacitor 10 will be described.

First, prior to soldering, the insulating film 22 is provided on the substrate 20. The insulating film 22 is provided, for example, so as to cover a portion of the land 30 including the peripheral edge portion 31. Next, a paste-like solder material is applied to a region of the land 30 that is not covered by the insulating film 22. Next, the multilayer ceramic capacitor 10 is provided at a predetermined position on the land 30. Then, by solidification of the solder material, the external electrode 16 and the land 30 are connected by the solder 40.

### Second Embodiment

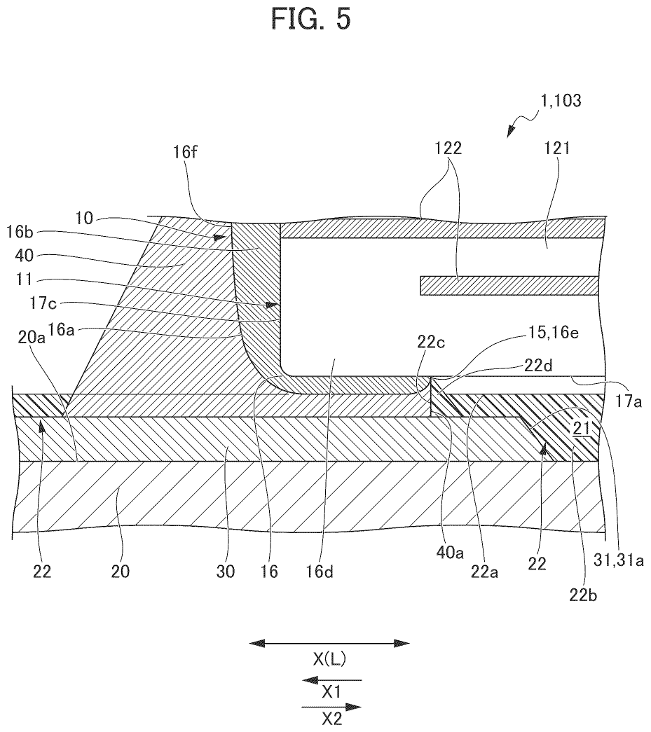

Next, the second embodiment will be described with reference to FIG. 5. The second embodiment is a modification of a portion of the above-described first embodiment. Therefore, in the reference drawings, the same reference numerals are assigned to the same components as those in the first embodiment, descriptions thereof are omitted, and mainly only the differences will be described.

The mounting configuration 103 of the second embodiment differs from the mounting configuration 101 of the first embodiment in the position of the opposing direction end portion 40a of the solder 40. In the mounting configuration 101 of the first embodiment shown in FIG. 4, the opposing direction end portion 40a is provided between the extension portion end portion 16e and the spacing direction end portion 16f in the X direction. Further, in the mounting configuration 101 of the first embodiment, the insulating film end portion 22c is located between the extension portion end portion 16e and the spacing direction end portion 16f in the X direction. In the mounting configuration 103 of the second embodiment, the insulating film end portion 22c is located at the extension portion end portion 16e in the X direction. The opposing direction end portion 40a is provided so as to face the insulating film end portion 22c in the X direction.

In the second embodiment, the above-described configuration makes it possible to suppress the solder 40 from contacting the component main body 11.

As shown in FIG. 5, the insulating film 22 may be provided with a portion where the insulating film 22 protrudes upward at the insulating film end portion 22c, such that the insulating film 22 contacts the extension portion end portion 16e. This protruding portion is referred to as an insulating film protruding portion 22d. The upward direction refers to a direction perpendicular to the surface 20a of the substrate 20 and away from the surface 20a.

By providing the insulating film protruding portion 22d, the solder 40 may more reliably be prevented from contacting the component main body 11.

### Third Embodiment

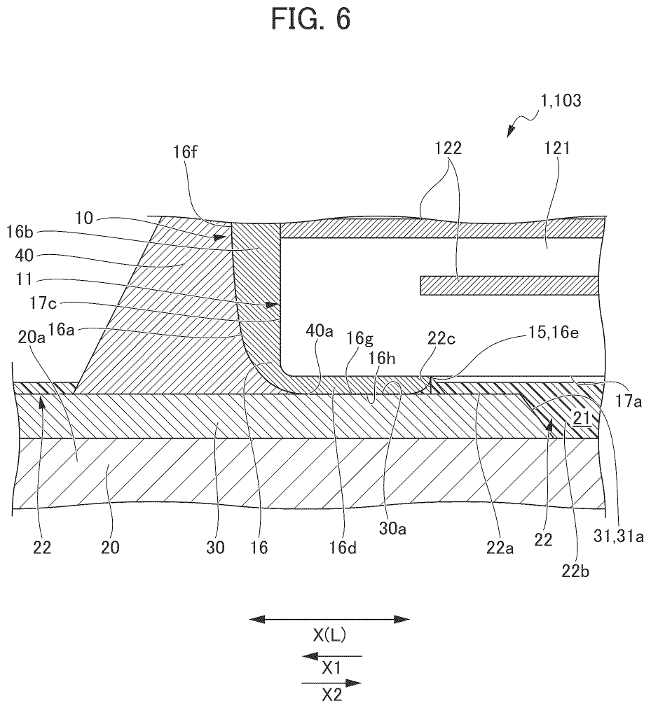

Next, a third embodiment will be described with reference to FIG. 6. The third embodiment is a modification of a portion of the above-described first embodiment. Therefore, in the reference drawings, the same reference numerals are assigned to the same components as those in the first embodiment, descriptions thereof are omitted, and mainly only differences will be described.

The mounting configuration 104 of the third embodiment differs from the mounting configuration 101 of the first embodiment in the position of the opposing direction end portion 40a of the solder 40. In the mounting configuration 101 of the first embodiment shown in FIG. 4, the opposing direction end portion 40a is provided between the extension portion end portion 16e and the spacing direction end portion 16f in the X direction. In the mounting configuration 104 of the third embodiment, as shown in FIG. 6, the opposing direction end portion 40a is provided near the end surface 17c in the X direction. This will be described below.

### (Extension Portion Flat Portion)

A surface of the land opposing extension portion 16d is referred to as an extension portion surface 16h. A surface of the land 30 is referred to as a land surface 30a. In the land opposing extension portion 16d, a portion where the extension portion surface 16h is parallel to the land surface 30a is referred to as an extension portion flat portion 16g. FIG. 6 indicates the position of the end portion of the extension portion flat portion 16g in the opposing direction X2. The position of the end portion of the extension portion flat portion 16g in the spacing direction X1 is indicated.

In the mounting configuration 104 of the third embodiment, the extension portion flat portion 16g of the land opposing extension portion 16d is in contact with the land 30 without the solder 40 interposed therebetween. Between the position of the end portion of the extension portion flat portion 16g in the opposing direction X2 and the position of the end portion of the extension portion flat portion 16g in the spacing direction X1, the solder 40 does not exist between the extension portion surface 16h and the land surface 30a. As illustrated in FIG. 6, in the third embodiment, the extension portion flat portion 16g of the external electrode 16 is disposed to overlap with the land 30 in the Z direction. Specifically, at least a portion of the extension portion flat portion 16g is in direct contact with the upper surface of the land 30. In this configuration, the solder 40 is not interposed between the extension portion flat portion 16g and the land 30 at the point of contact. This direct contact interface ensures a stable mechanical seating of the electronic component 10 on the substrate 20 and further limits the flow of solder 40 toward the opposing direction end portion 16e, thereby further suppressing the occurrence of cracks in the component main body 11.

The opposing direction end portion 40a of the solder 40 is located at the position E, which is the end portion of the extension portion flat portion 16g in the spacing direction X1.

In the third embodiment, the opposing direction end portion 40a is located more in the spacing direction X1 than the portion where the extension portion flat portion 16g and the land 30 are opposed to each other. Therefore, it is possible to reliably suppress the solder 40 from contacting the component main body 11.

The electrical conduction or continuity between the external electrode 16 and the land 30 is ensured by connecting the end surface 16a of the external electrode 16 and the land 30 with the solder 40.

Furthermore, the mounting configuration 104 of the third embodiment can be easily formed, for example, when the external electrode 16 includes a plated layer, by forming a tin-plated layer on the end surface 16a of the external electrode 16 and not forming a tin-plated layer on the extension portion flat portion 16g of the external electrode 16.

### Fourth Embodiment

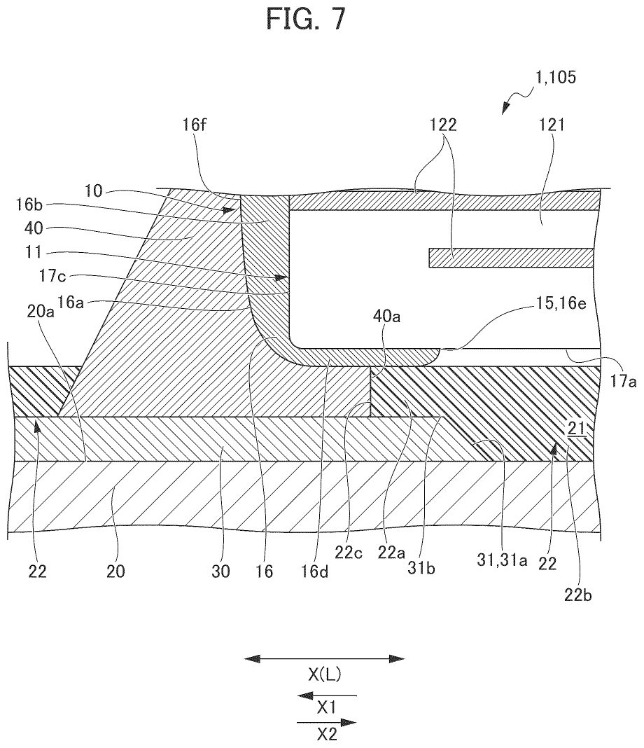

Next, a fourth embodiment will be described with reference to FIG. 7. The fourth embodiment is a modification of a portion of the above-described first embodiment. Therefore, in the reference drawings, the same reference numerals are assigned to the same components as those in the first embodiment, descriptions thereof are omitted, and mainly only the differences will be described.

### (Land Upper End Portion)

The mounting configuration 105 of the fourth embodiment differs from the mounting configuration 101 of the first embodiment in the position of the land 30. The upper end of the inner edge 31a of the land 30 is referred to as a land upper end portion 31b. The upward direction refers to a direction perpendicular to the surface 20a of the substrate 20 and away from the surface 20a, as described above. The position of the land upper end portion 31b in the X direction is indicated.

In the mounting configuration 101 of the first embodiment shown in FIG. 4, the land upper end portion 31b is located more in the opposing direction X2 than the extension portion end portion 16e. In the mounting configuration 105 of the fourth embodiment, as shown in FIG. 7, the land upper end portion 31b is located at the position of the extension portion end portion 16e.

Even when the land upper end portion 31b is located at the position of the extension portion end portion 16e, similarly to the mounting configuration 101 of the first embodiment, the opposing direction end portion 40a can be provided at any one of between the extension portion end portion 16e and the spacing direction end portion 16f or at the spacing direction end portion 16f.

For example, the insulating film end portion 22c of the on-land insulating film 22a is provided at a position where the opposing direction end portion 40a is desired to be provided. Then, the solder 40 is provided such that the opposing direction end portion 40a is in contact with the insulating film end portion 22c. This allows the opposing direction end portion 40a to be provided at a desired position.

The distance in the X direction between the land upper end portion 31b and the insulating film end portion 22c is defined as the on-land insulating film distance. The on-land insulating film distance is the length of the on-land insulating film 22a in the X direction. The on-land insulating film distance in the mounting configuration 105 of the fourth embodiment shown in FIG. 7 is shorter than the on-land insulating film distance in the mounting configuration 101 of the first embodiment shown in FIG. 4. That is, in the mounting configuration 105 of the fourth embodiment, the length of the on-land insulating film 22a in the X direction is shorter compared to the mounting configuration 101 of the first embodiment. Therefore, in the mounting configuration 105 of the fourth embodiment, it is possible to suppress variation in bonding strength between the multilayer ceramic capacitor 10 and the substrate 20 after mounting.

### Fifth Embodiment

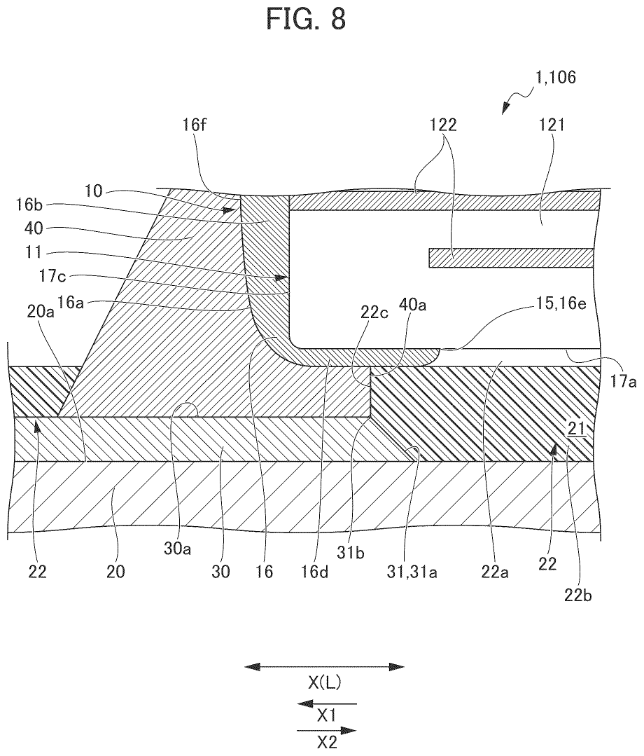

Next, the fifth embodiment will be described with reference to FIG. 8. The fifth embodiment is a modification of a portion of the first embodiment and the fourth embodiment described above. Therefore, in the reference drawings, the same reference numerals are assigned to the same components as those in the first embodiment and the fourth embodiment, descriptions thereof are omitted, and mainly only differences will be described.

The mounting configuration 106 of the fifth embodiment differs from the mounting configuration 101 of the first embodiment and the mounting configuration 105 of the fourth embodiment in the position of the land 30.

In the first embodiment shown in FIG. 4, the land upper end portion 31b is located more in the opposing direction X2 than the extension portion end portion 16e. In the fourth embodiment, the land upper end portion 31b is located at the same position as the extension portion end portion 16e. In the fifth embodiment, as shown in FIG. 8, the land upper end portion 31b is located more in the spacing direction X1 than the extension portion end portion 16e. In the fifth embodiment, the distance in the X direction between the two opposing lands 30 is shorter than the distance in the X direction between the two opposing extension portion end portions 16e.

In the mounting configuration 106 of the fifth embodiment, the opposing direction end portion 40a has difficulty in reaching the extension portion end portion 16e by traveling along the land surface 30a. This is because the land surface 30a exists only at a position more in the spacing direction X1 than the extension portion end portion 16e. Therefore, the mounting configuration 106 of the fifth embodiment makes it easier to suppress the solder 40 from contacting the component main body 11.

Furthermore, in the mounting configuration 106 of the fifth embodiment, the insulating film end portion 22c of the insulating film 22 is provided at a position where the opposing direction end portion 40a is desired to be provided. The opposing direction end portion 40a has difficulty in advancing beyond the insulating film end portion 22c. Therefore, it is possible for the mounting configuration 106 of the fifth embodiment to more reliably suppress the solder 40 from contacting the component main body 11.

### Sixth Embodiment

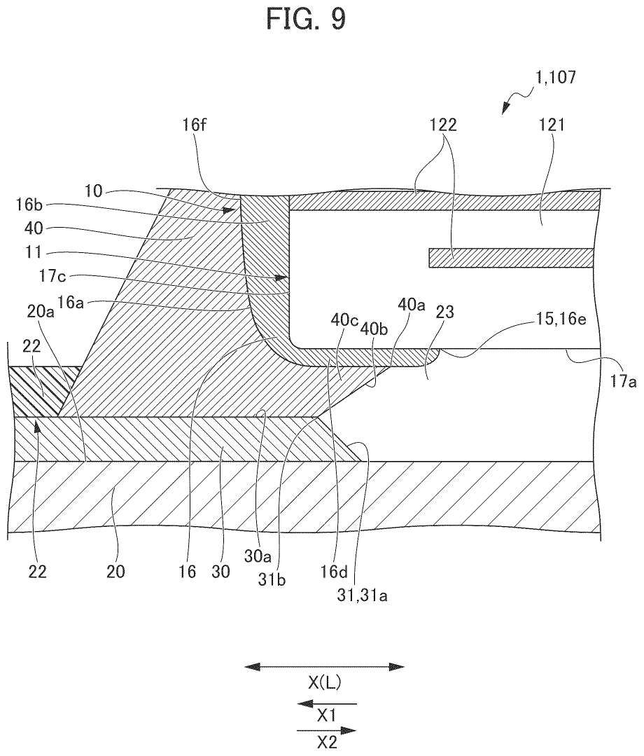

Next, the sixth embodiment will be described with reference to FIG. 9. The sixth embodiment is a modification of a portion of the above-described fifth embodiment. Therefore, in the reference drawings, the same reference numerals are assigned to the same components as those in the fifth embodiment, descriptions thereof are omitted, and mainly only the differences will be described.

The mounting configuration 107 of the sixth embodiment differs from the mounting configuration 106 of the fifth embodiment in the presence or absence of the insulating film 22. In the mounting configuration 106 of the fifth embodiment shown in FIG. 8, the insulating film 22 (inter-spacing portion insulating film 22b) is provided in the spacing portion 21. In the mounting configuration 107 of the sixth embodiment, as shown in FIG. 9, the insulating film 22 is not provided in the spacing portion 21. The portion where the inter-spacing portion insulating film 22b is provided in the mounting configuration 106 of the fifth embodiment corresponds to a void portion 23.

In the mounting configuration 107 of the sixth embodiment, the opposing direction end portion 40a does not contact the insulating film 22 in the opposing direction X2. Therefore, the solder 40 may spread along the land opposing extension portion 16d. The portion where the solder 40 spreads is referred to as a spreading portion 40c. In the example shown in FIG. 9, the spreading portion 40c of the solder 40 is provided in the vicinity of the opposing direction end portion 40a.

Also in the mounting configuration 107 of the sixth embodiment, the opposing direction end portion 40a is located at any one of between the extension portion end portion 16e and the spacing direction end portion 16f or at the spacing direction end portion 16f. This is because the land upper end portion 31b is provided at a position spaced apart by a predetermined distance in the spacing direction X1 from the extension portion end portion 16e.

In the mounting configuration 107 of the sixth embodiment, by providing the land upper end portion 31b at a predetermined position, it is possible to suppress the solder 40 from contacting the component main body 11 without providing the insulating film 22 as the inter-spacing portion insulating film 22b. In other words, in the mounting configuration 107 of the sixth embodiment, it is possible to suppress the solder 40 from contacting the component main body 11 without special consideration regarding the placement of the insulating film 22.

### Seventh Embodiment

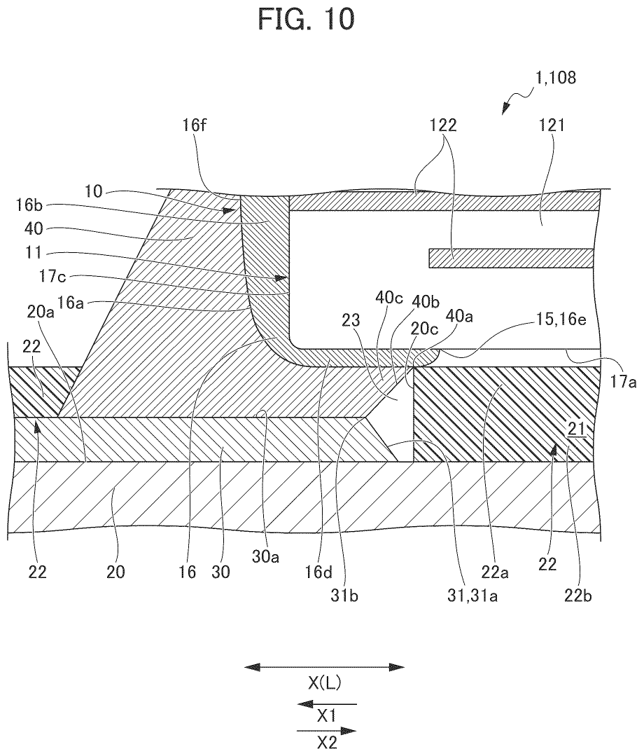

Next, a seventh embodiment will be described with reference to FIG. 10. The seventh embodiment is a modification of a portion of the above-described fifth embodiment and sixth embodiment. Therefore, in the reference drawings, the same reference numerals are assigned to the same components as those in the fifth embodiment and sixth embodiment, descriptions thereof are omitted, and mainly only differences will be described.

(Comparison with Fifth Embodiment)

The mounting configuration 108 of the seventh embodiment will be described in comparison with the mounting configuration 106 of the fifth embodiment. The mounting configuration 108 of the seventh embodiment differs from the mounting configuration 106 of the fifth embodiment in the length of the insulating film 22 existing in the spacing direction X1 from the extension portion end portion 16e.

The distance in the X direction from the extension portion end portion 16e to the insulating film end portion 22c is defined as an insulating film extension portion distance. The insulating film extension portion distance in the mounting configuration 108 of the seventh embodiment shown in FIG. 10 is shorter than the insulating film extension portion distance in the mounting configuration 106 of the fifth embodiment shown in FIG. 8. In the mounting configuration 106 of the fifth embodiment shown in FIG. 8, the insulating film end portion 22c extends beyond the extension portion end portion 16e to the land upper end portion 31b. In the mounting configuration 108 of the seventh embodiment shown in FIG. 10, the insulating film end portion 22c extends beyond the extension portion end portion 16e, but only to a position before reaching the land upper end portion 31b. Therefore, the insulating film extension portion distance in the mounting configuration 108 of the seventh embodiment is shorter than the insulating film extension portion distance in the mounting configuration 106 of the fifth embodiment.

In the mounting configuration 108 of the seventh embodiment, the insulating film end portion 22c is located more in the opposing direction X2. Therefore, the opposing direction end portion 40a is also located more in the opposing direction X2. As a result, the distance in the X direction where the solder 40 contacts the land opposing extension portion 16d becomes longer.

Regarding such a distance in the X direction between the opposing direction end portion 40a and the end surface 17c, such a distance in the mounting configuration 108 of the seventh embodiment shown in FIG. 10 is longer than such a distance in the mounting configuration 106 of the fifth embodiment shown in FIG. 8.

In this manner, by shortening the insulating film extension portion distance from the extension portion end portion 16e to the insulating film end portion 22c in the mounting configuration 108 of the seventh embodiment, the distance from the opposing direction end portion 40a to the end surface 17c becomes longer. As a result, it is possible to reduce the electrical resistance between the external electrode 16 and the land 30.

In the mounting configuration 108 of the seventh embodiment, the insulating film end portion 22c is provided in the spacing direction X1 beyond the extension portion end portion 16e. Therefore, contact of the solder 40 with the component main body 11 is suppressed.

(Comparison with Sixth Embodiment)

Next, the mounting configuration 108 of the seventh embodiment is described in comparison with the mounting configuration 107 of the sixth embodiment. The mounting configuration 108 of the seventh embodiment differs from the mounting configuration 107 of the sixth embodiment in the presence or absence of the insulating film 22. In the mounting configuration 107 of the sixth embodiment shown in FIG. 9, the insulating film 22 is not provided in the spacing portion 21. In the mounting configuration 108 of the seventh embodiment shown in FIG. 10, the insulating film 22 (inter-spacing portion insulating film 22b) is provided in the spacing portion 21.

As shown in FIG. 10, the inter-spacing portion insulating film 22b in the mounting configuration 108 of the seventh embodiment is provided to extend beyond the extension portion end portion 16e in the spacing direction X1. The inter-spacing portion insulating film 22b suppresses the solder 40 from being located at the extension portion end portion 16e and from contacting the component main body 11 beyond the extension portion end portion 16e.

Therefore, in the mounting configuration 108 of the seventh embodiment, the land upper end portion 31b can be located more in the opposing direction X2 compared to the mounting configuration 107 of the sixth embodiment. This is because in the mounting configuration 108 of the seventh embodiment, even when the solder 40 spreads in the opposing direction X2 starting from the land upper end portion 31b, the spreading of the solder 40 is stopped by the inter-spacing portion insulating film 22b before contacting the component main body 11.

By locating the land upper end portion 31b more in the opposing direction X2, it is possible to increase the length in the X direction where the solder 40 contacts the land opposing extension portion 16d. Regarding such a distance in the X direction between the opposing direction end portion 40a and the end surface 17c, such a distance in the mounting configuration 108 of the seventh embodiment shown in FIG. 10 is longer than such a distance in the mounting configuration 107 of the sixth embodiment shown in FIG. 9. By increasing such a distance in the X direction between the opposing direction end portion 40a and the end surface 17c, it is possible to reduce the electrical resistance between the external electrode 16 and the land 30.

In addition, by locating the land upper end portion 31b more in the opposing direction X2, alignment becomes easier when mounting the multilayer ceramic capacitor 10 on the substrate 20. While various embodiments describe the relationship between the solder 40 and the external electrodes 16, it should be understood that in any embodiment, a portion of the external electrode 16 may be in direct contact with the land 30 or the substrate 20 to define a solder-free zone that prevents mechanical stress transmission to the component main body 11.

The present disclosure is not limited to the above embodiments, and modifications and improvements within a scope achieving the objectives of the present disclosure are included in the present disclosure.

For example, the multilayer ceramic capacitor 10 in the present embodiment is merely an example of an electronic component, and the electronic component is not limited thereto, and other two-terminal electronic components such as inductors are also applicable. For example, in a case of an inductor, the component main body includes magnetic ceramics or the like.

In addition, the present disclosure includes the following combinations.

<1> A mounting configuration of an electronic component includes: a pair of lands provided on a substrate and spaced apart from each other in an opposed configuration; solder provided on each of the pair of lands; and an electronic component including a component main body including dielectric layers and internal electrode layers which are laminated, a pair of main surfaces opposed to each other in a lamination direction, a pair of lateral surfaces opposed to each other in a width direction orthogonal to the lamination direction, and a pair of end surfaces opposed to each other in a length direction orthogonal to the lamination direction and the width direction, and a pair of external electrodes each provided on a corresponding one of the pair of end surfaces, each of the pair of external electrodes being connected to each of the pair of lands via the solder. Each of the pair of external electrodes includes an extension portion extending to at least a portion of each of the pair of main surfaces and each of the pair of lateral surfaces, and

when a direction in which the pair of lands are aligned is defined as an X direction, a direction in which the pair of lands are spaced apart is defined as a spacing direction, and a direction in which the pair of lands are opposed to each other is defined as an opposing direction, an opposing direction end portion of the solder is located in the X direction at any one of between an opposing direction end portion of the extension portion and a spacing direction end portion of a corresponding one of the pair of external electrodes or at the spacing direction end portion of the corresponding one of the pair of external electrodes.

<2> In the mounting configuration of an electronic component as described in <1> above, a distance in the X direction between the opposing direction end portion of the extension portion and the opposing direction end portion of the solder is 5% or more and 100% or less of a distance in the X direction between the opposing direction end portion of the extension portion and a corresponding one of the pair of end surfaces.

<3> The mounting configuration of an electronic component as described in <1> or <2> above further includes an insulating film provided on the pair of lands, in which a spacing direction end portion of the insulating film is located at any one among at the opposing direction end portion of the extension portion, between the opposing direction end portion of the extension portion and the spacing direction end portion of a corresponding one of the pair of external electrodes, or at the spacing direction end portion of the corresponding one of the pair of external electrodes in the X direction.

<4> The mounting configuration of an electronic component as described in any one of <1> to <3> above further includes an insulating film provided on the pair of lands, in which the opposing direction end portion of the solder and the spacing direction end portion of the insulating film are in contact with each other.

<5> The mounting configuration of an electronic component as described in any one of <1> to <4> above further includes an insulating film provided on the substrate, in which a spacing direction end portion of the insulating film is located in the X direction at any one among at the opposing direction end portion of the extension portion, between the opposing direction end portion of the extension portion and the spacing direction end portion of a corresponding one of the pair of external electrodes, or at the spacing direction end portion of the corresponding one of the pair of external electrodes.

<6> The mounting configuration of an electronic component as described in any one of <1> to <5> above further includes an insulating film provided on the substrate, in which the opposing direction end portion of the solder and the spacing direction end portion of the insulating film are in contact with each other.

<7> The mounting configuration of an electronic component as described in any one of <1> to <6> above includes: a pair of lands provided on a substrate and spaced apart from each other in an opposed configuration; solder provided on each of the pair of lands; and an electronic component including a component main body including dielectric layers and internal electrode layers which are laminated, a pair of main surfaces opposed to each other in a lamination direction, a pair of lateral surfaces opposed to each other in a width direction orthogonal to the lamination direction, and a pair of end surfaces opposed to each other in a length direction orthogonal to the lamination direction and the width direction, and a pair of external electrodes each provided on a corresponding one of the pair of end surfaces, each of the pair of external electrodes being connected to each of the pairs of lands via the solder. Each of the pair of external electrodes includes an extension portion extending to at least a portion of each of the pair of main surfaces and each of the pair of lateral surfaces, and

when a direction in which the pair of lands are aligned is defined as an X direction, a direction in which the pair of lands are spaced apart is defined as a spacing direction, and a direction in which the pair of lands are opposed to each other is defined as an opposing direction, the opposing direction end portion of the solder is located in the X direction at any one of between a corresponding one of the pair of end surfaces and a spacing direction end portion of a corresponding one of the pair of external electrodes or at the spacing direction end portion of the corresponding one of the pair of external electrodes.

### EXPLANATION OF REFERENCE NUMERALS

1 mounting configuration
10 multilayer ceramic capacitor (electronic component)
16 external electrode
16c extension portion
16d land opposing extension portion
16e extension portion end portion
16f spacing direction end portion
16g extension portion flat portion
17c end surface
22 insulating film
22c insulating film end portion
30 land
31 peripheral edge portion
31b land upper end portion
40 solder
40a opposing direction end portion
X1 spacing direction
X2 opposing direction

1. A mounting configuration of an electronic component comprising:
a pair of lands provided on a substrate and spaced apart from each other;
an electronic component including a component main body and a pair of external electrodes, the component main body including dielectric layers and internal electrode layers which are laminated, the pair of external electrodes being disposed on opposite end surfaces of the component main body in a length direction; and
solder connecting each of the pair of external electrodes to a corresponding one of the pair of lands,
wherein each of the pair of external electrodes includes an extension portion extending from an end surface to at least a portion of a main surface of the component main body, and
wherein, when a direction in which the pair of lands are aligned is defined as an X direction, a direction in which the pair of lands are spaced apart is defined as a spacing direction, and a direction in which the pair of lands are opposed to each other is defined as an opposing direction, an opposing direction end portion of the solder is located in the X direction at a position between an opposing direction end portion of the extension portion and a spacing direction end portion of a corresponding external electrode or at the spacing direction end portion of the corresponding external electrode.

2. The mounting configuration of an electronic component according to claim 1, wherein a distance in the X direction between the opposing direction end portion of the extension portion and the opposing direction end portion of the solder is between 5% and 100%, inclusive, of a distance in the X direction between the opposing direction end portion of the extension portion and a corresponding end surface.

3. The mounting configuration of an electronic component according to claim 1, further comprising an insulating film provided on the pair of lands,
wherein a spacing direction end portion of the insulating film is located at any one among at the opposing direction end portion of the extension portion, between the opposing direction end portion of the extension portion and the spacing direction end portion of a corresponding external electrode, or at the spacing direction end portion of the corresponding external electrode in the X direction.

4. The mounting configuration of an electronic component according to claim 1, further comprising an insulating film provided on the pair of lands,
wherein the opposing direction end portion of the solder and the spacing direction end portion of the insulating film are in contact with each other.

5. The mounting configuration of an electronic component according to claim 1, further comprising an insulating film provided on the substrate,
wherein a spacing direction end portion of the insulating film is located in the X direction at any one among at the opposing direction end portion of the extension portion, between the opposing direction end portion of the extension portion and the spacing direction end portion of a corresponding external electrode, or at the spacing direction end portion of the corresponding external electrode.

6. The mounting configuration of an electronic component according to claim 1, further comprising an insulating film provided on the substrate,
wherein the opposing direction end portion of the solder and the spacing direction end portion of the insulating film are in contact with each other.

7. The mounting configuration according to claim 1, wherein the extension portion of each of the pair of external electrodes extends to at least a portion of each of a pair of lateral surfaces of the component main body, the pair of lateral surfaces being opposed to each other in a width direction orthogonal to both the lamination direction and the length direction.

8. The mounting configuration of an electronic component according to claim 1, further comprising
an insulating film disposed on the substrate, wherein the insulating film includes a protruding portion that protrudes in a direction away from the substrate beyond a surface of at least one of the pair of lands.

9. The mounting configuration according to claim 8, wherein the protruding portion of the insulating film is in contact with the opposing direction end portion of the solder.

10. The mounting configuration according to claim 1, wherein the extension portion of each external electrode includes a flat portion that is substantially parallel to a surface of the substrate.

11. The mounting configuration according to claim 10, wherein at least a portion of the flat portion is in direct contact with a surface of a corresponding land without the solder being interposed therebetween.

12. A mounting configuration of an electronic component, comprising:
a pair of lands on a substrate;
an electronic component including a component main body and a pair of external electrodes, each external electrode having an extension portion; and
solder connecting the external electrodes to the lands;
wherein at least a portion of each extension portion is in direct contact with a surface of a corresponding land without the solder being interposed therebetween, the direct contact forming a solder-free zone between the portion of each extension portion and the land surface.

13. The mounting configuration according to claim 12, wherein the component main body includes a ceramic material, and the solder is spaced apart from the ceramic material by a gap.

14. The mounting configuration according to claim 12, wherein a height of the solder in a Z direction perpendicular to the substrate is less than a height of the electronic component.

15. A mounting configuration for an electronic component, comprising:
a pair of lands disposed on a substrate;
an electronic component including a component main body and a pair of external electrodes, each of the pair of external electrodes having an extension portion; and
solder electrically connecting the pair of external electrodes to the pair of lands;
wherein, when a direction in which the pair of lands are aligned is defined as an X direction, a direction in which the pair of lands are spaced apart is defined as a spacing direction, and a direction in which the pair of lands are opposed to each other is defined as an opposing direction,
each land of the pair of lands includes a land upper end portion located further in the spacing direction than an extension portion end portion of a corresponding extension portion; and
wherein an opposing direction end portion of the solder is set back in the spacing direction from a boundary portion between the extension portion and the component main body.

16. The mounting configuration according to claim 15, further comprising a void portion defined by a region on the substrate between the pair of lands where an insulating film is absent.

17. The mounting configuration according to claim 16, wherein the void portion is located immediately adjacent to the land upper end portion.

18. The mounting configuration according to claim 15, wherein the solder forms a fillet having a concave profile between the land and the external electrode.
